(19) United States
(12) Patent Application Publication
(10) Pub. No.: US 2011/0049664 A1
(43) Pub. Date: Mar. 3, 2011

(54) EPITAXIAL SUBSTRATE FOR BACK-ILLUMINATED IMAGE SENSOR AND MANUFACTURING METHOD THEREOF

(75) Inventor: Kazunari Kurita, Tokyo (JP)

(73) Assignee: SUMCO CORPORATION, Tokyo (JP)

(21) Appl. No.: 12/872,674

(22) Filed: Aug. 31, 2010

(30) Foreign Application Priority Data
Sep. 1, 2009 (JP) 2009-201894
Sep. 2, 2009 (JP) 2009-202434
Sep. 4, 2009 (JP) 2009-204587

(51) Int. Cl. H01L 27/146; H01L 21/322; H01L 31/08

(52) U.S. Cl. 257/447; 438/58; 257/E21.318; 257/E27.13; 257/E31.052

(57) ABSTRACT

Provided is an epitaxial substrate for a back-illuminated image sensor and a manufacturing method thereof that is capable of suppressing metal contaminations and reducing occurrence of a white spot defect of the image sensor, by maintaining a sufficient gettering performance in a device process. The present invention includes forming a gettering sink immediately below a surface of a high-oxygen silicon substrate, forming a first epitaxial layer on the surface of the high-oxygen silicon substrate, and forming a second epitaxial layer on the first epitaxial layer, in which the step of forming the gettering sink includes forming an oxygen precipitate region by applying a long-time heat treatment at a temperature of 650-1150° C. to the high-oxygen silicon substrate.

### TECHNICAL FIELD

The present invention relates to an epitaxial substrate for a back-illuminated image sensor and a manufacturing method thereof, and in particular, to an epitaxial substrate for a back-illuminated image sensor for use in a digital video camera, a mobile phone and the like, and a manufacturing method thereof.

### BACKGROUND ART

Recently, a back-illuminated image sensor has been widely used because it can directly receive light from the outside, and take sharper images or motion pictures even in a dark place and the like due to the fact that a wiring layer and the like thereof are disposed at a lower layer than a sensor section. At the time of manufacturing such back-illuminated image sensor, there exists a case where a metal is incorporated in a semiconductor substrate as impurities. The metal incorporated in the semiconductor substrate causes the increase in a dark current of the image sensor, and generates a defect called a white spot defect.

The incorporation of the metal into the semiconductor substrate occurs in a process of forming a semiconductor epitaxial substrate and a process of forming an image sensor. It is considered that the metal contamination in the former process of forming the epitaxial substrate results from heavy metal particles coming from materials constituting an epitaxial growth furnace, or heavy metal particles generated from pipe materials corroded by chloride based gases used. Recently, these metal contaminations have been improved by various efforts such as changing the materials constituting the epitaxial growth furnace into an anti-corrosion material, but it is still difficult to completely avoid the metal contamination in the process of forming the semiconductor epitaxial substrate. On the other hand, in the latter process of forming the image sensor, there is a concern that the heavy metal contamination of the semiconductor substrate occurs in the processes such as ion implantation, diffusion and oxidizing heat treatment.

For these reasons, conventionally, the heavy metal contamination of the semiconductor substrate is avoided by forming, in the semiconductor substrate, a gettering sink for capturing the metal, or using a substrate, such as a high-concentration boron substrate, having high ability (gettering performance) to capture the metal.

In general, the gettering sink is formed in the semiconductor substrate by using an intrinsic gettering (IG) method in which an oxygen precipitate is formed within the semiconductor substrate, or an extrinsic gettering (EG) method in which the gettering sink is formed on a rear surface of the semiconductor substrate. However, in a case of the EG method described above, there was a problem that a damage such as a backside damage is formed on the rear surface, and particles are generated from the rear surface in the process of forming the semiconductor epitaxial substrate or image sensor, which further generates a defective factor in the image sensor.

JP 2002-353434 Laid-open discloses a technique for forming a gettering sink, in which a carbon implantation region is formed in a semiconductor substrate by using a carbon ion implantation method, which is one type of the IG method described above, and then, heat treatment is applied in the process of forming an image sensor.

Further, JP 2009-73684 Laid-open discloses a technique in which a semiconductor substrate is rapidly heated and cooled to form a vacancy in advance in the vicinity of a surface of the semiconductor substrate, and then, an epitaxial layer is grown on the semiconductor substrate. This vacancy serves as a core of oxygen precipitation in a heat treatment applied in a process of forming an image sensor, and an oxygen precipitate region is formed, which becomes a gettering sink.

However, these techniques form the gettering sink through the heat treatment for growing the epitaxial layer in the process of forming the semiconductor epitaxial substrate, or the heat treatment in the process of forming the image sensor, which leads to a problem that the gettering performance obtained in these processes is not sufficient. Further, in JP 2002-353434 Laid-open, there exists a problem that, by subjecting the semiconductor substrate having the carbon implantation region formed therein to the high-temperature heat treatment, crystal defects (crystal lattice distortion and the like) generated by the carbon implantation is relaxed, and the function as the gettering sink deteriorates. Therefore, an upper limitation is set to the treatment temperature. Yet further, in JP 2009-73684 Laid-open, there exists a problem that, by subjecting the semiconductor substrate having a vacancy formed therein to the high-temperature heat treatment, the vacancy is dispersed, and the oxygen precipitate region cannot be sufficiently formed.

### DISCLOSURE OF THE INVENTION

### Problems to be Solved by the Invention

An object of the present invention is to provide an epitaxial substrate for a back-illuminated image sensor and a manufacturing method thereof that can solve the problems described above, and maintain a sufficient gettering performance during a device process, whereby it is possible to suppress metal contaminations and reduce occurrence of a white spot defect of the image sensor.

### Means for Solving the Problems

In order to achieve the object described above, main configurations of the present inventions are as follows:

(1) A method of manufacturing an epitaxial substrate for a back-illuminated image sensor, the method which includes the steps of: forming a gettering sink immediately below a surface of a high-oxygen silicon substrate; forming a first epitaxial layer on the surface of the high-oxygen silicon substrate; and, forming a second epitaxial layer on the first epitaxial layer, in which the step of forming the gettering sink includes forming an oxygen precipitate region by applying a long-time heat treatment at a temperature of 650-1150° C. to the high-oxygen silicon substrate.

(2) The method of manufacturing an epitaxial substrate for a back-illuminated image sensor according to (1) described above, in which the long-time heat treatment includes: performing a low-temperature heat treatment in which the high-oxygen silicon substrate is heated to a first temperature ranging from 650 to 900° C. at a rate of 0.5-3° C./min and the first temperature is maintained for 20 minutes to four hours; and, then, performing a high-temperature heat treatment in which the high-oxygen silicon substrate is heated to a second temperature ranging from 1000 to 1150° C. at a rate of 3-5° C./min and the second temperature is maintained for 30 minutes to four hours.

(3) The method of manufacturing an epitaxial substrate for a back-illuminated image sensor according to (1) described above, in which an oxygen concentration of the high-oxygen silicon substrate before the formation of the gettering sink is in the range of 1.0×10¹⁸ to 1.0×10²⁰ atom/cm³.

(4) The method of manufacturing an epitaxial substrate for a back-illuminated image sensor according to (1) described above, in which a density of an oxygen precipitate of the oxygen precipitate region after the formation of the gettering sink and before the formation of the first epitaxial layer is in the range of 1×10⁵ to 1×10⁷/cm².

(5) An epitaxial substrate for a back-illuminated image sensor manufactured by the method of manufacturing an epitaxial substrate for a back-illuminated image sensor according to (1) described above, in which an oxygen concentration of the oxygen precipitate region is in the range of 1.0×10¹⁸ to 1.0×10²⁰ atom/cm³.

(6) The epitaxial substrate for a back-illuminated image sensor according to (5) described above, in which an impurity concentration of the first epitaxial layer is in the range of 1×10¹⁶ to 1×10²⁰ atom/cm³.

(7) A method of manufacturing an epitaxial substrate for a back-illuminated image sensor, the method which includes the steps of: forming a gettering sink immediately below a surface of a carbon-added silicon substrate having a carbon concentration of 5.0×10¹⁵ to 10×10¹⁶ atom/cm³; forming a first epitaxial layer on the surface of the carbon-added silicon substrate; and, forming a second epitaxial layer on the first epitaxial layer, in which the step of forming the gettering sink includes forming a carbon-oxygen-based precipitate region by applying a long-time heat treatment at a temperature of 600-1150° C. to the carbon-added silicon substrate.

(8) The method of manufacturing an epitaxial substrate for a back-illuminated image sensor according to (7) described above, in which the long-time heat treatment includes: performing a low-temperature heat treatment in which the carbon-added silicon substrate is heated to a temperature ranging from 600 to 900° C. at a rate of 0.5-3° C./min and this state is maintained for 20 minutes to four hours; and then, performing a high-temperature heat treatment in which the carbon-added silicon substrate is heated to a temperature ranging from 1000 to 1150° C. at a rate of 3-5° C./min and this state is maintained for 0.5 to four hours.

(9) The method of manufacturing an epitaxial substrate for a back-illuminated image sensor according to (7) described above, in which a density of a carbon-oxygen-based precipitate in the carbon-oxygen-based precipitate region after the formation of the gettering sink and before the formation of the first epitaxial layer is in the range of 1×10⁵ to 1×10⁷/cm².

(10) An epitaxial substrate for a back-illuminated image sensor manufactured by the method of manufacturing an epitaxial substrate for a back-illuminated image sensor according to (7) described above, in which a carbon concentration of the carbon-oxygen-based precipitate region is in the range of 5.0×10¹⁵ to 10×10¹⁶ atom/cm³, and, an oxygen concentration of the carbon-oxygen-based precipitate region is in the range of 1.0×10¹⁸ to 1.0×10¹⁹ atom/cm³.

(11) A method of manufacturing an epitaxial substrate for a back-illuminated image sensor, the method which includes the steps of: forming a gettering sink immediately below a surface of a carbon-added silicon substrate having a carbon concentration of 5.0×10¹⁵ to 10×10¹⁶ atom/cm³; forming a first epitaxial layer on the surface of the carbon-added silicon substrate; and, forming a second epitaxial layer on the first epitaxial layer, in which the step of forming the gettering sink includes forming a carbon-oxygen-based precipitate region by applying a high-temperature and short-time heat treatment at a temperature of 1135-1280° C. to the carbon-added silicon substrate, and then applying a long-time heat treatment at a temperature lower than that in the high-temperature and short-time heat treatment within the range of 600 to 1150° C.

(12) The method of manufacturing an epitaxial substrate for a back-illuminated image sensor according to (11) described above, in which the high-temperature and short-time heat treatment includes: heating the carbon-added silicon substrate to a first temperature ranging from 1135 to 1285° C. at a rate of 75° C./min or lower; maintaining the first temperature for 1-5 seconds; and, cooling the carbon-added silicon substrate to a temperature of 700° C. at a rate of 100° C./min or lower.

(13) The method of manufacturing an epitaxial substrate for a back-illuminated image sensor according to (11) described above, in which the long-time heat treatment includes: performing a low-temperature heat treatment in which the carbon-added silicon substrate is heated to a second temperature ranging from 600 to 900° C. at a rate of 0.5-3° C./min or lower and the second temperature is maintained for 20 minutes to three hours; and then, performing a high-temperature treatment in which the carbon-added silicon substrate is heated to a third temperature ranging from 1000 to 1150° C. at a rate of 3-5° C./min and the third temperature is maintained for 30 minutes to four hours.

(14) The method of manufacturing an epitaxial substrate for a back-illuminated image sensor according to (11) described above, in which a density of a carbon-oxygen-based precipitate in the carbon-oxygen-based precipitate region after the formation of the gettering sink and before the formation of the first epitaxial layer is in the range of 1×10⁵ to 1×10⁷/cm² immediately below a surface of the carbon-added silicon substrate, and is in the range of 1×10³ to 1×10⁵/cm² at a thickness center of the carbon-added silicon substrate.

(15) An epitaxial substrate for a back-illuminated image sensor manufactured by the method of manufacturing an epitaxial substrate for a back-illuminated image sensor according to (11) described above, in which a carbon concentration of the carbon-oxygen-based precipitate region is in the range of 5.0×10¹⁵ to 10×10¹⁶ atom/cm³, and, an oxygen concentration of the carbon-oxygen-based precipitate region is in the range of 1.0×10¹⁸ to 1.0×10¹⁹ atom/cm³.

(16) The method of manufacturing an epitaxial substrate for a back-illuminated image sensor according to (1), (7), or (11) described above, in which a step of polishing and cleaning the substrate is inserted after the step of forming the gettering sink and before the step of forming the first epitaxial layer.

(17) The epitaxial substrate for a back-illuminated image sensor according to (10) or (15) described above, in which an impurity concentration of the first epitaxial layer is in the range of 1×10¹⁶ to 1×10¹⁹ atom/cm³.

(18) The epitaxial substrate for a back-illuminated image sensor according to (5), (10) or (15) described above, in which an impurity concentration of the second epitaxial layer is in the range of 1×10¹⁴ to 1×10¹⁶ atom/cm³.

### Effect of the Invention

According to a first aspect of the present invention, it is possible to provide an epitaxial substrate for a back-illuminated image sensor and a manufacturing method thereof that is capable of suppressing metal contaminations and reducing occurrence of a white spot defect of the image sensor by subjecting a high-oxygen silicon substrate to a long-time heat treatment to maintain a sufficient gettering performance in a device process.

According to a second aspect of the present invention, it is possible to provide an epitaxial substrate for a back-illuminated image sensor and a manufacturing method thereof that is capable of suppressing metal contaminations and reducing occurrence of a white spot defect of the image sensor by subjecting a carbon-added silicon substrate to a long-time heat treatment to maintain a sufficient gettering performance in a device process.

According to a third aspect of the present invention, it is possible to provide an epitaxial substrate for a back-illuminated image sensor and a manufacturing method thereof that is capable of suppressing metal contaminations and reducing occurrence of a white spot defect of the image sensor by subjecting a carbon-added silicon substrate to a high-temperature and short-time heat treatment and then to a long-time heat treatment at a temperature lower than the temperature of the high-temperature and short-time heat treatment to maintain a sufficient gettering performance in a device process.

### BRIEF DESCRIPTION OF DRAWINGS

FIG. 1A through FIG. 1C are schematic sectional views for explaining a manufacturing method of an epitaxial substrate for a back-illuminated image sensor according to a first and a second embodiments of the present invention;

FIG. 2 is an example of a graph showing density distribution of oxygen precipitate or carbon-oxygen-based precipitate of the epitaxial substrate for a back-illuminated image sensor according to the first and the second embodiments of the present invention;

FIG. 3A through FIG. 3C are schematic sectional views for explaining a manufacturing method of an epitaxial substrate for a back-illuminated image sensor according to a third embodiment of the present invention; and,

FIG. 4 is an example of a graph showing density distribution of carbon-oxygen-based precipitate of the epitaxial substrate for a back-illuminated image sensor according to the third embodiment of the present invention.

### MODE FOR CARRYING OUT THE INVENTION

Hereinbelow, embodiments of an epitaxial substrate for a back-illuminated image sensor and a manufacturing method thereof according to a first embodiment and a second embodiment of the present invention will be described with reference to the drawings. FIG. 1A through FIG. 1C are schematic sectional views for explaining a method of manufacturing a back-illuminated image sensor according to the present invention. Note that, in FIG. 1, a thickness direction is amplified for the sake of explanation.

As shown in FIG. 1A through FIG. 1C, an epitaxial substrate 100 for a back-illuminated image sensor according to a first embodiment of the present invention is manufactured by: preparing a high-oxygen silicon substrate 1 (FIG. 1A); forming a gettering sink 2 immediately below a surface of the high-oxygen silicon substrate 1 (FIG. 1B); forming a first epitaxial layer 3 on the surface of the high-oxygen silicon substrate 1; and, forming a second epitaxial layer 4 on the first epitaxial layer 3 (FIG. 1C), and the step (FIG. 1B) of forming the gettering sink 2 includes forming an oxygen precipitate region 2 by subjecting the high-oxygen silicon substrate 1 to a long-time heat treatment. With this process, it is possible to provide an epitaxial substrate for a back-illuminated image sensor and a manufacturing method thereof that can maintain a sufficient gettering performance during a device process, thereby suppressing metal contaminations, and reducing occurrence of a white spot defect in the image sensor.

In this specification, the device process means an epitaxial-layer growth process in a semiconductor epitaxial substrate forming process and an image sensor forming process.

It is preferable that the range of an oxygen concentration of the high-oxygen silicon substrate 1 before the gettering sink is formed is from 1.0×10¹⁸ to 1.0×10²⁰ atom/cm³. This is because the oxygen precipitate functioning as the gettering sink 2 cannot be formed sufficiently in a case where the oxygen concentration is less than 1.0×10¹⁸ atom/cm³, and on the other hand, a size of each oxygen precipitate is less than 50 nm in a case where the oxygen concentration exceeds 1.0×10²⁰ atom/cm³, whereby the sufficient gettering performance cannot be maintained.

A long-time heat treatment is applied at a temperature of 650-1150° C. In particular, it is preferable that this long-time heat treatment include a low-temperature heat treatment in which the high-oxygen silicon substrate 1 is heated to a first temperature ranging from 650 to 900° C. at a rate of 0.5-3° C./min and the first temperature is maintained for 20 minutes to four hours; and, then, a high-temperature heat treatment in which the high-oxygen silicon substrate 1 is heated to a second temperature ranging from 1000-1150° C. at a rate of 3-5° C./min and the second temperature is maintained for 30 minutes to four hours. With this process, the oxygen precipitate is precipitated as described above, and the oxygen precipitate region 2 is formed in the high-oxygen silicon substrate 1. It is preferable that the long-time heat treatment be performed under an atmosphere of oxygen gas or mixture gas of oxygen and nitrogen in order to promote growth of the oxygen precipitate.

The range of the oxygen concentration of the oxygen precipitate region 2 formed as described above is from 1.0×10¹⁸ to 1.0×10²⁰ atom/cm³. This is because, in a case where the oxygen concentration is less than 1.0×10¹⁸ atom/cm³, precipitation is not promoted, which leads to a low oxygen precipitation density. On the other hand, the precipitation becomes excessive in a case where the oxygen concentration exceeds 1.0×10²⁰ atom/cm³. At this time, a concentration of interstitial oxygen of the high-oxygen silicon substrate 1 decreases as compared with that before the gettering sink described above is formed.

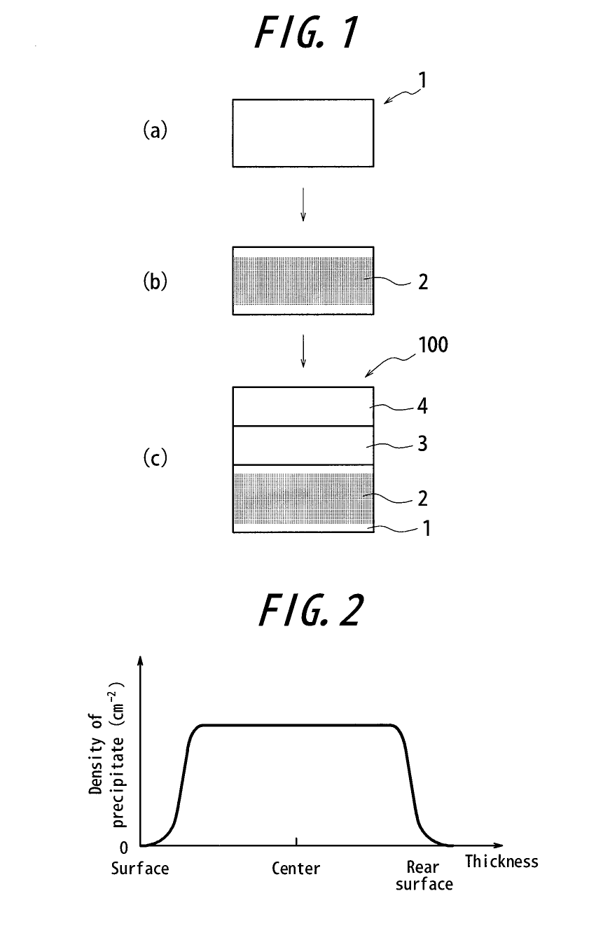

Further, it is preferable that the range of a density of oxygen precipitate in the oxygen precipitate region is from 1×10⁵ to 1×10⁷/cm². This is because the increase in the oxygen precipitate density is effective for improving the gettering performance. However, in a case where the oxygen precipitate density exceeds 1×10⁷/cm², the size of the oxygen precipitate tends to decrease, and distortion energy is relaxed, possibly leading to decrease in the gettering performance. FIG. 2 is a graph showing an example of density distribution of oxygen precipitate, and showing density distribution that extends uniformly from a position immediately below a surface (within 50 μm from a front surface or rear surface in a thickness direction) to a thickness center.

Yet further, it is preferable that a step of polishing and cleaning the high-oxygen silicon substrate 1 be inserted after the gettering sink is formed (FIG. 1B) and before the first epitaxial layer is formed (FIG. 1C). This makes it possible to obtain an effect in which an oxidized film and organic substances can be removed from the surface of the substrate. Note that the cleaning may be made by such a method as an RCA cleaning in which SC-1 and SC-2 are combined.

It is preferable that the range of a concentration of impurities in the first epitaxial layer is from 1×10¹⁶ to 1×10²⁰ atom/cm³. The resistance possibly becomes too high in a case where the concentration of impurities is less than 1×10¹⁶ atom/cm³, and on the other hand, misfit dislocation possibly occurs in a case where the concentration of impurities exceeds 1×10²⁰ atom/cm³. Further, it is preferable to use, for example, B or P as additional elements. It is preferable to form the first epitaxial layer by performing the epitaxial growth process for 150-240 sec at 1050-1100° C. under an atmosphere of trichlorosilane gas in order to suppress the reduction in the concentration of impurities in the vicinity of the substrate surface caused by outward diffusion of the impurities.

It is preferable that the range of the concentration of impurities in the second epitaxial layer is from 1×10¹⁴ to 1×10¹⁶ atom/cm³. This is because, in a case where the concentration of impurities is less than 1×10¹⁴ atom/cm³, a spatial charge layer of p-n junction is brought into contact with the first epitaxial layer, possibly adversely affecting electrical characteristics thereof. On the other hand, in a case where the concentration of impurities exceeds 1×10¹⁶ atom/cm³, misfit dislocation possibly occurs at an interface of the epitaxial layer, and an etching rate possibly decreases due to the increase in the concentration of impurities. Further, it is preferable to use, for example, B or P as additional elements. It is preferable to form the second epitaxial layer by performing the epitaxial growth process for 60-120 sec at 1100-1150° C. under an atmosphere of trichlorosilane gas in order to suppress the interfacial reaction with the first epitaxial layer caused by outward diffusion of the impurities.

Next, as shown in FIG. 1A through FIG. 1C, an epitaxial substrate 100 for a back-illuminated image sensor according to a second embodiment of the present invention is manufactured by: preparing a carbon-added silicon substrate 1 (FIG. 1A); forming a gettering sink 2 immediately below a surface of the carbon-added silicon substrate 1 (FIG. 1B); forming a first epitaxial layer 3 on the surface of the carbon-added silicon substrate 1; and, forming a second epitaxial layer 4 on the first epitaxial layer 3 (FIG. 1C), and the step (FIG. 1B) of forming the gettering sink 2 includes forming a carbon-oxygen-based precipitate region by subjecting the carbon-added silicon substrate 1 to a long-time heat treatment. With this process, it is possible to provide an epitaxial substrate for a back-illuminated image sensor and a manufacturing method thereof that can maintain a sufficient gettering performance during a device process, thereby suppressing metal contaminations, and reducing occurrence of a white spot defect in the image sensor.

In this specification, the carbon-oxygen-based precipitate described above means a precipitate formed by carbon-oxygen composite (cluster) containing carbon, and the device process means an epitaxial-layer growth process in a semiconductor epitaxial substrate forming process and an image sensor forming process.

The range of a carbon concentration of the carbon-added silicon substrate 1 is from 5.0×10¹⁵ to 10×10¹⁶ atom/cm³. This is because the carbon-oxygen-based precipitate functioning as the gettering sink 2 cannot be formed sufficiently in a case where the carbon concentration is less than 5.0×10¹⁵ atom/cm³, and on the other hand, a size of each carbon-oxygen-based precipitate is less than 50 nm in a case where the carbon concentration exceeds 10×10¹⁶ atom/cm³, whereby the sufficient gettering performance cannot be maintained. Note that the carbon-added silicon substrate 1 may contain carbon in a solid solution state. This makes it possible to introduce carbon into a silicon lattice as substitution for silicon. Since the atomic radius of carbon is smaller than that of silicon atom, stress field of crystal becomes compressive stress field, and oxygen and impurities in the lattice are likely to be captured by the compressive stress field, in a case where carbon is placed in a substitution position. By applying a predetermined heat treatment, high density oxide-based precipitate having dislocation therein likely appears from a substitution position where carbon is placed, and the carbon-added silicon substrate 1 can obtain a high gettering effect.

A long-time heat treatment is applied at a temperature of 600-1150° C. In particular, it is preferable that this long-time heat treatment include a low-temperature heat treatment in which the carbon-added silicon substrate 1 is heated to 600-900° C. at a rate of 0.5-3° C./min and this state is maintained for 20 minutes to four hours; and then, a high-temperature heat treatment in which the carbon-added silicon substrate 1 is heated to 1000-1150° C. at a rate of 3-5° C./min and, this state is maintained for 0.5 to four hours. With this process, the carbon-oxygen-based precipitate is precipitated as described above, and the carbon-oxygen-based precipitate region is formed in the carbon-added silicon substrate 1. It is preferable that the long-time heat treatment be performed under an atmosphere of oxygen gas or mixture gas of oxygen and nitrogen in order to promote growth of the oxygen precipitate.

The range of the carbon concentration of the carbon-oxygen-based precipitate region formed as described above is from 5.0×10¹⁵ to 10×10¹⁶ atom/cm³, and the range of the oxygen concentration is from 1.0×10¹⁸ to 1.0×10¹⁹ atom/cm³. In a case where the carbon concentration is less than 5.0×10¹⁵ atom/cm³, precipitation of oxygen is not promoted, and precipitation density of the carbon-oxygen-based precipitate becomes low, possibly leading to a case where sufficient gettering performance cannot be obtained. On the other hand, in a case where the carbon concentration exceeds 10×10¹⁶ atom/cm³, the precipitation density of the carbon-oxygen-based precipitate becomes too high, and the size of the carbon-oxygen-based precipitate becomes extremely small, whereby sufficient distortion effect cannot be obtained, possibly leading to reduction in the gettering performance. Further, in a case where the oxygen concentration is less than 1.0×10¹⁸ atom/cm³, precipitation of oxygen is suppressed, and the precipitation density of carbon-oxygen-based precipitate becomes low, possibly leading to a case where the sufficient gettering performance cannot be obtained. On the other hand, in a case where the oxygen concentration exceeds 1.0×10¹⁹ atom/cm³, the precipitation density of the carbon-oxygen-based precipitate becomes too high, the size of the carbon-oxygen-based precipitate becomes large, possibly leading to a case where second dislocation extends to the epitaxial layer.

Further, it is preferable that the range of the density of the carbon-oxygen-based precipitate in the carbon-oxygen-based precipitate region is from 1×10⁵ to 1×10⁷/cm². This is because the increase in the oxygen precipitate density is effective for improving the gettering performance. However, when the oxygen precipitate density exceeds 1×10⁷/cm², a size of the oxygen precipitate tends to decrease, and distortion energy is relaxed, possibly leading to decrease in the gettering performance. Similar to the first embodiment described above, density distribution of carbon-oxygen-based precipitate extends uniformly from a position immediately below a surface (within 50 μm from a front surface or rear surface in a thickness direction) to a thickness center, as shown in FIG. 2.

It is preferable that the range of a concentration of impurities in the first epitaxial layer is from 1×10¹⁶ to 1×10¹⁹ atom/cm³. The resistance possibly becomes too high in a case where the concentration of impurities is less than 1×10¹⁶ atom/cm³, and on the other hand, misfit dislocation possibly occurs due to the occurrence of lattice distortion in a case where the concentration of impurities exceeds 1×10¹⁹ atom/cm³. Further, it is preferable to use, for example, B or P as additional elements. It is preferable to form the first epitaxial layer by performing the epitaxial growth process for 150-240 sec at 1050-1100° C. under an atmosphere of trichlorosilane gas in order to suppress the reduction in the concentration of impurities in the vicinity of the substrate surface caused by outward diffusion of the impurities.

Additionally, similar to the first embodiment described above, a step of polishing and cleaning the carbon-added silicon substrate 1 be further inserted after the gettering sink is formed (FIG. 1B) and before the first epitaxial layer is formed (FIG. 1C). Also, the range of the impurity concentration of the second epitaxial layer is the same as that in the first embodiment described above.

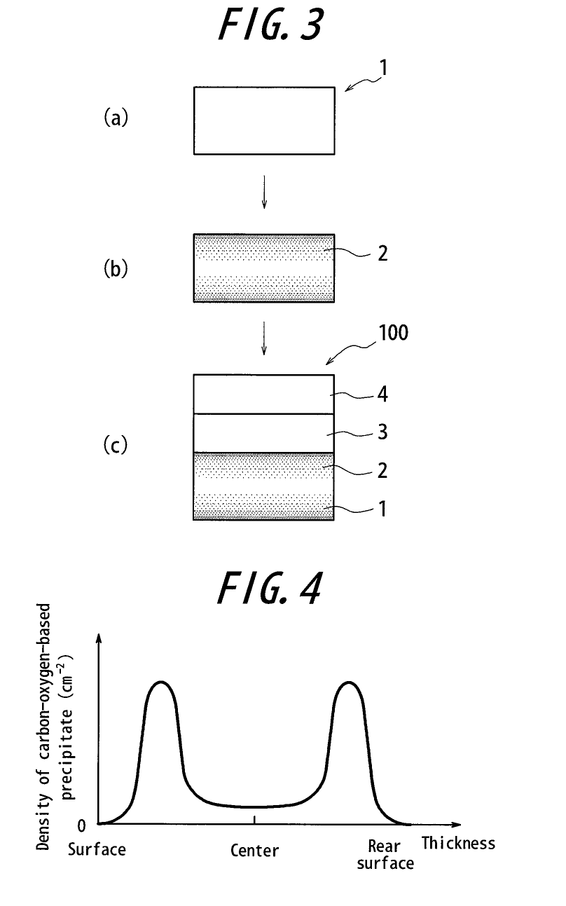

Next, an embodiment of an epitaxial substrate for a back-illuminated image sensor and a manufacturing method thereof according to a third embodiment of the present invention will be described with reference to the drawings. FIG. 3A through FIG. 3C are schematic sectional views for explaining a manufacturing method of a back-illuminated image sensor according to the present invention. Note that, in FIG. 3, a thickness direction is amplified for the sake of explanation.

As shown in FIG. 3A through FIG. 3C, an epitaxial substrate 100 for a back-illuminated image sensor according to a third embodiment of the present invention is manufactured by: preparing a carbon-added silicon substrate 1 (FIG. 3A); forming a gettering sink 2 immediately below a surface of the carbon-added silicon substrate 1 (FIG. 3B); forming a first epitaxial layer 3 on the surface of the carbon-added silicon substrate 1; and, forming a second epitaxial layer 4 on the first epitaxial layer 3 (FIG. 3C), and the step (FIG. 3B) of forming the gettering sink 2 includes forming a carbon-oxygen-based precipitate region 2 by subjecting a carbon-added silicon substrate to a high-temperature and short-time heat treatment and then to a long-time heat treatment at a temperature lower than that of the high-temperature and short-time heat treatment. With this process, it is possible to provide an epitaxial substrate for a back-illuminated image sensor and a manufacturing method thereof that can maintain a sufficient gettering performance during a device process, thereby suppressing metal contaminations, and reducing occurrence of a white spot defect in the image sensor.

A high-temperature and short-time heat treatment is applied at a temperature of 1135-1280° C. In particular, it is preferable that this high-temperature and short-time heat treatment include: heating to a first temperature that falls in 1135-1285° C. at a rate of 75° C./min or lower; maintaining this state for 1-5 seconds; and, then, cooling to 700° C. at a rate of 100° C./min or lower. With this process, a surface of the carbon-added silicon substrate 1 is nitrided; vacancies are implanted; and, a vacancy-implanted layer with high density is formed in the vicinity of the substrate surface. It is preferable that this high-temperature and short-time heat treatment be performed under an atmosphere of nitrogen gas or mixture gas of nitrogen and argon in order to promote vacancy implantation by nitridation reaction in the vicinity of the substrate surface.

A long-time heat treatment is applied at a temperature of 600-1150° C. In particular, it is preferable that this long-time heat treatment include a low-temperature heat treatment in which the carbon-added silicon substrate 1 is heated to 600-900° C. at a rate of 0.5-3° C./min and this state is maintained for 20 minutes to four hours; and, a high-temperature heat treatment in which the carbon-added silicon substrate 1 is heated to 1000-1150° C. at a rate of 3-5° C./min and, this state is maintained for 30 minutes to four hours. With this process, it is possible to fixate the vacancies formed in the high-temperature and short-time heat treatment and prevent the vacancies from dispersing even if heat treatment is applied in the epitaxial layer forming process (FIG. 3C) and the image sensor forming process thereafter. It is preferable that the long-time heat treatment be performed under an atmosphere of oxygen gas or mixture gas of oxygen and nitrogen in order to promote growth of the oxygen precipitate.

The range of the carbon concentration of the carbon-oxygen-based precipitate region 2 formed as described above is from 5.0×10¹⁵ to 10×10¹⁶ atom/cm³, and the range of the oxygen concentration thereof is from 1.0×10¹⁸ to 1.0×10¹⁹ atom/cm³. This is because the oxygen precipitate density becomes low in a case where the carbon concentration is less than 5.0×10¹⁵ atom/cm³, and on the other hand, precipitation becomes excessive in a case where the carbon concentration exceeds 10×10¹⁶ atom/cm³. Also, oxygen precipitation is suppressed and an oxygen precipitate concentration becomes low in a case where the oxygen concentration is less than 1.0×10¹⁸ atom/cm³, and on the other hand, precipitation becomes excessive in a case where the oxygen concentration exceeds 1.0×10¹⁹ atom/cm³.

Further, it is preferable that the range of the density of the carbon-oxygen-based precipitate in the carbon-oxygen-based precipitate region is from 1×10⁵ to 1×10⁷/cm² at a position immediately below the surface of the carbon-added silicon substrate, and is from 1×10³ to 1×10⁵/cm² at a thickness center of the carbon-added silicon substrate, for the purpose of enhancing the gettering performance in a region immediately below the epitaxial layer. FIG. 4 is a graph showing an example of density distribution of the carbon-oxygen-based precipitate. As shown in FIG. 4, when the density of the carbon-oxygen-based precipitate is in a so-called “M shape,” a high density oxygen precipitate region is formed immediately below the epitaxial layer, which means that the silicon substrate has a high gettering performance as compared with a case where the density is formed in a uniform manner.

Additionally, similar to the second embodiment described above, it is preferable that a step of polishing and cleaning the carbon-added silicon substrate 1 be further inserted after the gettering sink is formed (FIG. 3B) and before the first epitaxial layer is formed (FIG. 3C). Also, the range of the impurity concentration of each of the first epitaxial layer and the second epitaxial layer is the same as that in the second embodiment described above.

Note that FIG. 1 through FIG. 4 only show typical examples of the embodiments, and the present invention is not limited to these embodiments.

### Examples

Next, sample epitaxial substrates for a back-illuminated image sensor according to the present invention were prepared, and performances thereof are evaluated, which will be described below.

### Experiment Example 1

### Example 1-1

In Example 1-1, a sample epitaxial substrate for a back-illuminated image sensor is prepared such that a high-oxygen silicon substrate 1 (oxygen concentration: 1.6×10¹⁸ atom/cm³) is subjected to a long-time heat treatment (heating to 900° C. at a rate of 1° C./min; maintaining this state for one hour to perform a low-temperature heat treatment; then, heating to 1000° C. at a rate of 3° C./min; and, maintaining this state for one hour) to form an oxygen precipitate region (oxygen concentration: 1.6×10¹⁸ atom/cm³, oxygen precipitate density: 1×10⁷/cm²) and obtain a gettering sink immediately below a surface of the high-oxygen silicon substrate; this high-oxygen silicon substrate is polished and cleaned; and, a first epitaxial layer (adding B, B concentration: 1×10¹⁶ atom/cm³) and a second epitaxial layer (adding B, B concentration: 1×10¹⁵ atom/cm³) are formed sequentially on a surface of the high-oxygen silicon substrate, as shown in FIG. 1.

### Example 1-2

A sample wafer for a back-illuminated image sensor is prepared through a process similar to that of Example 1-1, except that the long-time heat treatment is applied such that the high-oxygen silicon substrate is heated to 850° C. at a rate of 2° C./min; this state is maintained for two hours to perform a low-temperature heat treatment; then, the high-oxygen silicon substrate is heated to 1150° C. at a rate of 4° C./min; and this state is maintained for four hours.

### Example 1-3

A sample wafer for a back-illuminated image sensor is prepared through a process similar to that of Example 1-1, except that the high-oxygen silicon substrate is not polished and cleaned in the process.

### Example 1-4

A sample wafer for a back-illuminated image sensor is prepared through a process similar to that of Example 1-1, except that a high-oxygen silicon substrate having an oxygen concentration of 1.7×10¹⁸ atom/cm³ is employed in the process.

### Example 1-5

A sample wafer for a back-illuminated image sensor is prepared through a process similar to that of Example 1-1, except that a first epitaxial layer having P added thereto and having P concentration of 1×10¹⁶ atom/cm³ is formed in the process.

### Example 1-6

A sample wafer for a back-illuminated image sensor is prepared through a process similar to that of Example 1-1, except that a second epitaxial layer having P added thereto and having P concentration of 1×10¹⁵ atom/cm³ is formed in the process.

### Comparative Example 1-1

A sample wafer for a back-illuminated image sensor is prepared through a process similar to that of Example 1-1, except that the long-time heat treatment is not performed in the process.

(Evaluation)

For each of the samples prepared in Examples 1-1 through 1-6 and Comparative Example 1-1, a carbon concentration and an oxygen concentration in an oxygen precipitate region as well as a density of an oxygen precipitate are measured by using an infrared absorption spectroscopy, and metal contamination and white spot defect thereof are evaluated, results of which are shown in Table 1. An evaluation method thereof will be described below.

(Metal Contamination)

The prepared samples are evaluated under the following criteria such that surfaces of the prepared samples are contaminated with nickel (1.0×10¹² atoms/cm²) by using a spin coat contamination method; heat treatment is applied at 900° C. for one hour; the surfaces of the samples are subjected to a selective etching; and, a defect density (number/cm²) on each of the surfaces of the samples is measured.
⊚: less than 5 number/cm²
◯: 5 number/cm² through less than 50 number/cm²
×: 50 number/cm² or more

(White Spot Defect)

Suppression of occurrence of white spot defect is evaluated under the following criteria such that back-illuminated image sensors are manufactured by using the prepared samples; leakage current of a photodiode under the dark environment is measured for the manufactured back-illuminated image sensors by using a semiconductor parameter analyzer, and is converted into pixel data (data concerning number of white spot defect); and the number of white spot defect per unit area (1 cm²) is measured.
⊚: 5 or less
◯: over 5 through 50
×: over 50

TABLE 1

| | Oxygen | | | |
|---|---|---|---|---|
| | concentration in | Density of | Metal | white |
| | oxygen precipitate | oxygen | contam- | spot |
| | region (atom/cm³) | precipitate (/cm²) | ination | defect |
| Example 1-1 | 1.6 × 10¹⁸ | 1.00 × 10⁷ | ⊚ | ⊚ |
| Example 1-2 | 1.6 × 10¹⁸ | 8.00 × 10⁶ | ⊚ | ⊚ |
| Example 1-3 | 1.6 × 10¹⁸ | 1.00 × 10⁷ | ◯ | ◯ |
| Example 1-4 | 1.7 × 10¹⁸ | 2.00 × 10⁷ | ⊚ | ⊚ |
| Example 1-5 | 1.6 × 10¹⁸ | 1.45 × 10⁷ | ⊚ | ⊚ |
| Example 1-6 | 1.6 × 10¹⁸ | 1.45 × 10⁷ | ⊚ | ⊚ |
| Comparative | 1.6 × 10¹⁸ | 8.50 × 10⁵ | X | X |
| Example 1-1 | | | | |

From the results shown in Table 1, it can be known that, in Examples 1-1 through 1-6, occurrence of metal contamination and white spot defect is suppressed, and sufficient gettering performance can be maintained in the device process, as compared with Comparative Example 1-1.

### Experiment Example 2

### Example 2-1

In Example 2-1, a sample epitaxial substrate for a back-illuminated image sensor is prepared such that a carbon-added silicon substrate (carbon concentration: 1×10¹⁶ atom/cm³) is subjected to a long-time heat treatment (heating to 900° C. at a rate of 1° C./min; maintaining this state for one hour to perform a low-temperature heat treatment; heating to 1000° C. at a rate of 3° C./min; and, maintaining this state for one hour) to form a carbon-oxygen-based precipitate region (carbon concentration: 1×10¹⁶ atom/cm³, oxygen concentration: 15×10¹⁷ atom/cm³, and density of carbon-oxygen-based precipitate: 1×10⁶/cm²) and to obtain a gettering sink immediately below a surface of the carbon-added silicon substrate; this carbon-added silicon substrate is polished and cleaned; and then, a first epitaxial layer (adding B, B concentration: 1×10¹⁶ atom/cm³) and a second epitaxial layer (adding B, B concentration: 1×10¹⁵ atom/cm³) are formed sequentially on a surface of the carbon-added silicon substrate, as shown in FIG. 1.

### Example 2-2

A sample wafer for a back-illuminated image sensor is prepared through a process similar to that of Example 2-1, except that the long-time heat treatment is applied such that the carbon-added silicon substrate is heated to 850° C. at a rate of 3° C./min; this state is maintained for two hours to perform a low-temperature heat treatment; the carbon-added silicon substrate is heated to 1150° C. at a rate of 5° C./min: and this state is maintained for two hours.

### Example 2-3

A sample wafer for a back-illuminated image sensor is prepared through a process similar to that of Example 2-1, except that the carbon-added silicon substrate is not polished and cleaned in the process.

### Example 2-4

A sample wafer for a back-illuminated image sensor is prepared through a process similar to that of Example 2-1, except that a first epitaxial layer having P added thereto and having P concentration of 1×10¹⁶ atom/cm³ is formed in the process.

### Example 2-5

A sample wafer for a back-illuminated image sensor is prepared through a process similar to that of Example 2-1, except that a second epitaxial layer having P added thereto and having P concentration of 1×10¹⁵ atom/cm³ is formed in the process.

### Comparative Example 2-1

A sample wafer for a back-illuminated image sensor is prepared through a process similar to that of Example 2-1, except that a carbon-added silicon substrate having a carbon concentration of 1×10¹⁵ atom/cm³ is employed in the process.

### Comparative Example 2-2

A sample wafer for a back-illuminated image sensor is prepared through a process similar to that of Example 2-1, except that a non-doped carbon-added silicon substrate is employed in the process.

### Comparative Example 2-3

A sample wafer for a back-illuminated image sensor is prepared through a process similar to that of Example 2-1, except that the long-time heat treatment is not performed in the process.

(Evaluation)

For each of the samples prepared in Examples 2-1 through 2-5 and Comparative Examples 2-1 through 2-3, a carbon concentration and an oxygen concentration in a carbon-oxygen-based precipitate region as well as a density of a carbon-oxygen-based precipitate are obtained by using an infrared absorption spectroscopy (FT-IR: Fourier transform infrared spectroscopy, conversion factor of old ASTM: fc=4.81), and metal contamination and white spot defect thereof are evaluated, results of which are shown in Table 2. An evaluation method thereof will be described below.

(Metal Contamination)

The prepared samples are evaluated under the following criteria such that surfaces of the prepared samples are contaminated with nickel (1.0×10¹² atoms/cm²) by using a spin coat contamination method; heat treatment is applied at 900° C. for one hour; the surfaces of the samples are subjected to a selective etching; and, a defect density (number/cm²) on each of the surfaces of the samples is measured.
No metal contamination: less than 10 number/cm²
Metal contamination exists: 10 number/cm² or more

(White Spot Defect)

Back-illuminated image sensors are manufactured by using the prepared samples; leakage current of a photodiode under the dark environment is measured for the manufactured back-illuminated image sensors by using a semiconductor parameter analyzer, and is converted into pixel data (data concerning number of white spot defect); and the number of white spot defect per unit area (1 cm²) is measured.

TABLE 2

| | Carbon-oxygen-based precipitate | | | | |
|---|---|---|---|---|---|
| | region | | | | |
| | Carbon | Oxygen | Density of | Metal | White |
| | concentration | concentration | carbon-oxygen-based | contam- | spot |
| | (atom/cm³) | (atom/cm³) | precipitate (/cm²) | ination | defect |
| Example 2-1 | 1.00 × 10¹⁶ | 1.50 × 10¹⁸ | 1.00 × 10⁶ | No | Five |
| | | | | | or less |
| Example 2-2 | 1.00 × 10¹⁶ | 1.50 × 10¹⁸ | 5.80 × 10⁵ | No | Five |
| | | | | | or less |
| Example 2-3 | 1.00 × 10¹⁶ | 1.50 × 10¹⁸ | 1.00 × 10⁶ | No | Five |
| | | | | | or less |
| Example 2-4 | 1.00 × 10¹⁶ | 1.50 × 10¹⁸ | 1.00 × 10⁶ | No | Five |
| | | | | | or less |
| Example 2-5 | 1.00 × 10¹⁶ | 1.50 × 10¹⁸ | 1.00 × 10⁶ | No | Five |
| | | | | | or less |
| Comparative | 1.00 × 10¹⁵ | 1.50 × 10¹⁹ | 1.20 × 10⁵ | Exist | 20 or |
| Example 2-1 | | | | | less |
| Comparative | — | 1.50 × 10¹⁸ | 1.00 × 10⁴ | Exist | 50 or |
| Example 2-2 | | | | | less |
| Comparative | 1.00 × 10¹⁶ | 1.50 × 10¹⁸ | 4.00 × 10⁵ | Exist | 15 or |
| Example 2-3 | | | | | less |

From the results shown in Table 2, it can be known that, in Examples 2-1 through 2-5, occurrence of metal contamination and white spot defect is suppressed, and sufficient gettering performance can be maintained in the device process, as compared with Comparative Examples 2-1 through 2-3.

### Experiment Example 3

### Example 3-1

In Example 3-1, a sample epitaxial substrate for a back-illuminated image sensor is prepared such that a carbon-added silicon substrate (carbon concentration: 1×10¹⁶ atom/cm³) is subjected to a high-temperature and short-time heat treatment (heating to 1280° C. at a rate of 75° C./min; maintaining this state for five seconds; then, cooling to 700° C. at a rate of 100° C./min), and then is subjected to a long-time heat treatment (heating to 900° C. at a rate of 1° C./min; maintaining this state for one hour to perform a low-temperature heat treatment; then, heating to 1000° C. at a rate of 3 ° C./min; and, maintaining this state for one hour) to form a carbon-oxygen-based precipitate region (carbon concentration: 1×10¹⁶ atom/cm³, oxygen concentration: 1.5×10¹⁸ atom/cm³, density at a position immediately below a surface of the carbon-added silicon substrate: 1×10⁶/cm², and density at a thickness center of the carbon-added silicon substrate: 8×10⁵/cm²) and to obtain a gettering sink immediately below the surface of the carbon-added silicon substrate; this carbon-added silicon substrate is polished and cleaned; and, a first epitaxial layer (adding B, B concentration: 1×10¹⁶ atom/cm³) and a second epitaxial layer (adding B, B concentration: 1×10¹⁵ atom/cm³) are formed sequentially on a surface of the carbon-added silicon substrate, as shown in FIG. 3.

### Example 3-2

A sample wafer for a back-illuminated image sensor is prepared through a process similar to that of Example 3-1, except that the long-time and short-time heat treatment is applied such that the carbon-added silicon substrate is heated to 1250° C. at a rate of 80° C./min; this state is maintained for 10 seconds; and then, the carbon-added silicon substrate is cooled to 700° C. at a rate of 75° C./min.

### Example 3-3

A sample wafer for a back-illuminated image sensor is prepared through a process similar to that of Example 3-1, except that the long-time heat treatment is applied such that the carbon-added silicon substrate is heated to 950° C. at a rate of 1° C./min; this state is maintained for two hours to perform a low-temperature heat treatment; then, the carbon-added silicon substrate is heated to 1050° C. at a rate of 4° C./min: and this state is maintained for two hours.

### Example 3-4

A sample wafer for a back-illuminated image sensor is prepared through a process similar to that of Example 3-1, except that the carbon-added silicon substrate is not polished and cleaned in the process.

### Example 3-5

A sample wafer for a back-illuminated image sensor is prepared through a process similar to that of Example 3-1, except that a first epitaxial layer having P added thereto and having P concentration of 1×10¹⁶ atom/cm³ is formed in the process.

### Example 3-6

A sample wafer for a back-illuminated image sensor is prepared through a process similar to that of Example 3-1, except that a second epitaxial layer having P added thereto and having P concentration of 1×10¹⁵ atom/cm³ is formed in the process.

### Comparative Example 3-1

A sample wafer for a back-illuminated image sensor is prepared through a process similar to that of Example 3-1, except that a carbon-added silicon substrate having a carbon concentration of 1×10¹⁵ atom/cm³ is employed in the process.

### Comparative Example 3-2

A sample wafer for a back-illuminated image sensor is prepared through a process similar to that of Example 3-1, except that a non-doped silicon substrate is employed in the process.

### Comparative Example 3-3

A sample wafer for a back-illuminated image sensor is prepared through a process similar to that of Example 3-1, except that the long-time heat treatment is not performed in the process.

### Comparative Example 3-4

A sample wafer for a back-illuminated image sensor is prepared through a process similar to that of Example 3-1, except that the high-temperature and short-time heat treatment is not performed in the process.

### Comparative Example 3-5

A sample wafer for a back-illuminated image sensor is prepared through a process similar to that of Example 3-1, except that the high-temperature and short-time heat treatment and the long-time heat treatment are not performed in the process.

(Evaluation)

For each of the samples prepared in Examples 3-1 through 3-6 and Comparative Examples 3-1 through 3-5, a carbon concentration and an oxygen concentration in a carbon-oxygen-based precipitate region, and a density of a carbon-oxygen-based precipitate are obtained by using an infrared absorption spectroscopy, and metal contamination and white spot defect thereof are evaluated, results of which are shown in Table 3.

The evaluation is made in a manner similar to that of Experiment Example 1 described above.

TABLE 3

| | | | Density of | | | |
|---|---|---|---|---|---|---|
| | Carbon-oxygen-based | | carbon-oxygen-based | | | |
| | precipitate region | | precipitate (/cm²) | | | |
| | Carbon | Oxygen | Immediately | | Metal | White |
| | concentration | concentration | below | Thickness | contam- | spot |
| | (atom/cm³) | (atom/cm³) | surface | center | ination | defect |
| Example 3-1 | 1.00 × 10¹⁶ | 1.50 × 10¹⁸ | 1.00 × 10⁶ | 8.00 × 10⁵ | ⊚ | ⊚ |
| Example 3-2 | 1.00 × 10¹⁶ | 1.50 × 10¹⁸ | 5.00 × 10⁶ | 1.00 × 10⁶ | ◯ | ◯ |
| Example 3-3 | 1.00 × 10¹⁶ | 1.50 × 10¹⁸ | 1.20 × 10⁷ | 1.10 × 10⁷ | ◯ | ◯ |
| Example 3-4 | 1.00 × 10¹⁶ | 1.50 × 10¹⁸ | 1.20 × 10⁷ | 8.00 × 10⁵ | ◯ | ◯ |
| Example 3-5 | 1.00 × 10¹⁶ | 1.50 × 10¹⁸ | 1.20 × 10⁷ | 8.00 × 10⁵ | ⊚ | ⊚ |
| Example 3-6 | 1.00 × 10¹⁶ | 1.50 × 10¹⁸ | 1.20 × 10⁷ | 8.00 × 10⁵ | ⊚ | ⊚ |
| Comparative | 1.00 × 10¹⁵ | 1.50 × 10¹⁸ | 5.00 × 10⁵ | 1.00 × 10⁵ | X | X |
| Example 3-1 | | | | | | |
| Comparative | — | 1.50 × 10¹⁸ | 8.00 × 10⁴ | 1.00 × 10³ | X | X |
| Example 3-2 | | | | | | |
| Comparative | 1.00 × 10¹⁵ | 1.50 × 10¹⁸ | 8.00 × 10³ | 1.00 × 10³ | X | X |
| Example 3-3 | | | | | | |
| Comparative | 1.00 × 10¹⁵ | 1.50 × 10¹⁸ | 6.00 × 10³ | 1.00 × 10³ | X | X |
| Example 3-4 | | | | | | |
| Comparative | 1.00 × 10¹⁵ | 1.50 × 10¹⁸ | 2.00 × 10³ | 1.00 × 10³ | X | X |
| Example 3-5 | | | | | | |

From the results shown in Table 3, it can be known that, in Examples 3-1 through 3-6, occurrence of metal contamination and white spot defect is suppressed, and sufficient gettering performance is maintained in the device process, as compared with Comparative Examples 3-1 through 3-5.

### INDUSTRIAL APPLICABILITY

According to a first aspect of the present invention, it is possible to provide an epitaxial substrate for a back-illuminated image sensor and a manufacturing method thereof that is capable of suppressing metal contaminations and reducing occurrence of a white spot defect of the image sensor by subjecting a high-oxygen silicon substrate to a long-time heat treatment to maintain a sufficient gettering performance in a device process.

According to a second aspect of the present invention, it is possible to provide an epitaxial substrate for a back-illuminated image sensor and a manufacturing method thereof that is capable of suppressing metal contaminations and reducing occurrence of a white spot defect of the image sensor by subjecting a carbon-added silicon substrate to a long-time heat treatment to maintain s sufficient gettering performance in a device process.

According to a third aspect of the present invention, it is possible to provide an epitaxial substrate for a back-illuminated image sensor and a manufacturing method thereof that is capable of suppressing metal contaminations and reducing occurrence of a white spot defect of the image sensor by subjecting a carbon-added silicon substrate to a high-temperature and short-time heat treatment and then to a long-time heat treatment at a temperature lower than the temperature of the high-temperature and short-time heat treatment to maintain a sufficient gettering performance in a device process.

### EXPLANATION OF REFERENCE NUMERALS

1 High-oxygen silicon substrate or carbon-added silicon substrate
2 Precipitate region (oxygen precipitate region or carbon-oxygen-based precipitate region)
3 First epitaxial layer
4 Second epitaxial layer
100 Epitaxial substrate for back-illuminated image sensor

What is claimed is:

1. A method of manufacturing an epitaxial substrate for a back-illuminated image sensor, the method comprising the steps of:
forming a gettering sink immediately below a surface of a high-oxygen silicon substrate;
forming a first epitaxial layer on the surface of the high-oxygen silicon substrate; and,
forming a second epitaxial layer on the first epitaxial layer, wherein
the step of forming the gettering sink includes forming an oxygen precipitate region by applying a long-time heat treatment at a temperature of 650-1150° C. to the high-oxygen silicon substrate.

2. The method of manufacturing an epitaxial substrate for a back-illuminated image sensor according to claim 1, wherein
the long-time heat treatment includes:
performing a low-temperature heat treatment in which the high-oxygen silicon substrate is heated to a first temperature ranging from 650 to 900° C. at a rate of 0.5-3° C./min and the first temperature is maintained for 20 minutes to four hours; and, then,
performing a high-temperature heat treatment in which the high-oxygen silicon substrate is heated to a second temperature ranging from 1000 to 1150° C. at a rate of 3-5° C./min and the second temperature is maintained for 30 minutes to four hours.

3. The method of manufacturing an epitaxial substrate for a back-illuminated image sensor according to claim 1, wherein
an oxygen concentration of the high-oxygen silicon substrate before the formation of the gettering sink is in the range of 1.0×10¹⁸ to 1.0×10²⁰ atom/cm³.

4. The method of manufacturing an epitaxial substrate for a back-illuminated image sensor according to claim 1, wherein
a density of an oxygen precipitate of the oxygen precipitate region after the formation of the gettering sink and before the formation of the first epitaxial layer is in the range of 1×10⁵ to 1×10⁷/cm².

5. An epitaxial substrate for a back-illuminated image sensor manufactured by the method of manufacturing an epitaxial substrate for a back-illuminated image sensor according to claim 1, wherein
an oxygen concentration of the oxygen precipitate region is in the range of 1.0×10¹⁸ to 1.0×10²⁰ atom/cm³.

6. The epitaxial substrate for a back-illuminated image sensor according to claim 5, wherein
an impurity concentration of the first epitaxial layer is in the range of 1×10¹⁶ to 1×10²⁰ atom/cm³.

7. A method of manufacturing an epitaxial substrate for a back-illuminated image sensor, the method comprising the steps of:
forming a gettering sink immediately below a surface of a carbon-added silicon substrate having a carbon concentration of 5.0×10¹⁵ to 10×10¹⁶ atom/cm³;
forming a first epitaxial layer on the surface of the carbon-added silicon substrate; and,
forming a second epitaxial layer on the first epitaxial layer, wherein
the step of forming the gettering sink includes forming a carbon-oxygen-based precipitate region by applying a long-time heat treatment at a temperature of 600-1150° C. to the carbon-added silicon substrate.

8. The method of manufacturing an epitaxial substrate for a back-illuminated image sensor according to claim 7, wherein
the long-time heat treatment includes:
performing a low-temperature heat treatment in which the carbon-added silicon substrate is heated to a temperature ranging from 600 to 900° C. at a rate of 0.5-3° C./min and this state is maintained for 20 minutes to four hours; and then,
performing a high-temperature heat treatment in which the carbon-added silicon substrate is heated to a temperature ranging from 1000 to 1150° C. at a rate of 3-5° C./min and this state is maintained for 0.5 to four hours.

9. The method of manufacturing an epitaxial substrate for a back-illuminated image sensor according to claim 7, wherein
a density of a carbon-oxygen-based precipitate in the carbon-oxygen-based precipitate region after the formation of the gettering sink and before the formation of the first epitaxial layer is in the range of 1×10⁵ to 1×10⁷/cm².

10. An epitaxial substrate for a back-illuminated image sensor manufactured by the method of manufacturing an epitaxial substrate for a back-illuminated image sensor according to claim 7, wherein
a carbon concentration of the carbon-oxygen-based precipitate region is in the range of 5.0×10¹⁵ to 10×10¹⁶ atom/cm³, and,
an oxygen concentration of the carbon-oxygen-based precipitate region is in the range of 1.0×10¹⁸ to 1.0×10¹⁹ atom/cm³.

11. A method of manufacturing an epitaxial substrate for a back-illuminated image sensor, the method comprising the steps of:
forming a gettering sink immediately below a surface of a carbon-added silicon substrate having a carbon concentration of 5.0×10¹⁵ to 10×10¹⁶ atom/cm³;
forming a first epitaxial layer on the surface of the carbon-added silicon substrate; and,
forming a second epitaxial layer on the first epitaxial layer, wherein
the step of forming the gettering sink includes forming a carbon-oxygen-based precipitate region by applying a high-temperature and short-time heat treatment at a temperature of 1135-1280° C. to the carbon-added silicon substrate, and then applying a long-time heat treatment at a temperature lower than that in the high-temperature and short-time heat treatment within the range of 600 to 1150° C.

12. The method of manufacturing an epitaxial substrate for a back-illuminated image sensor according to claim 11, wherein
the high-temperature and short-time heat treatment includes:
heating the carbon-added silicon substrate to a first temperature ranging from 1135 to 1285° C. at a rate of 75° C./min or lower;
maintaining the first temperature for 1-5 seconds; and,
cooling the carbon-added silicon substrate to a temperature of 700° C. at a rate of 100° C./min or lower.

13. The method of manufacturing an epitaxial substrate for a back-illuminated image sensor according to claim 11, wherein
the long-time heat treatment includes:
performing a low-temperature heat treatment in which the carbon-added silicon substrate is heated to a second temperature ranging from 600 to 900° C. at a rate of 0.5-3° C./min or lower and the second temperature is maintained for 20 minutes to three hours; and then,
performing a high-temperature treatment in which the carbon-added silicon substrate is heated to a third temperature ranging from 1000 to 1150° C. at a rate of 3-5° C./min and the third temperature is maintained for 30 minutes to four hours.

14. The method of manufacturing an epitaxial substrate for a back-illuminated image sensor according to claim 11, wherein
a density of a carbon-oxygen-based precipitate in the carbon-oxygen-based precipitate region after the formation of the gettering sink and before the formation of the first epitaxial layer is in the range of 1×10⁵ to 1×10⁷/cm² immediately below a surface of the carbon-added silicon substrate, and is in the range of 1×10³ to 1×10⁵/cm² at a thickness center of the carbon-added silicon substrate.

15. An epitaxial substrate for a back-illuminated image sensor manufactured by the method of manufacturing an epitaxial substrate for a back-illuminated image sensor according to claim 11, wherein
a carbon concentration of the carbon-oxygen-based precipitate region is in the range of 5.0×10¹⁵ to 10×10¹⁶ atom/cm³, and, an oxygen concentration of the carbon-oxygen-based precipitate region is in the range of 1.0×10¹⁸ to 1.0×10¹⁹ atom/cm³.

16. The method of manufacturing an epitaxial substrate for a back-illuminated image sensor according to claim 1, 7, or 11, wherein
a step of polishing and cleaning the substrate is inserted after the step of forming the gettering sink and before the step of forming the first epitaxial layer.

17. The epitaxial substrate for a back-illuminated image sensor according to claim 10 or 15, wherein
an impurity concentration of the first epitaxial layer is in the range of 1×10¹⁶ to 1×10¹⁹ atom/cm³.

18. The epitaxial substrate for a back-illuminated image sensor according to claim 5, 10 or 15, wherein
an impurity concentration of the second epitaxial layer is in the range of 1×10¹⁴ to 1×10¹⁶ atom/cm³.
